(19) United States
(12) Patent Application Publication
(10) Pub. No.: US 2026/0241495 A1
(43) Pub. Date: Aug. 20, 2026

(54) DIFFUSION SOLDERING METHOD AND SOLDER MATERIAL

(71) Applicant: Infineon Technologies AG, Neubiberg (DE)

(72) Inventors: Steffen JORDAN, Pielenhofen (DE); Edmund RIEDL, Wald (DE); Alexander HEINRICH, Bad Abbach (DE); Catharina WILLE, Regensburg (DE)

(73) Assignee: Infineon Technologies AG, Neubiberg (DE)

(21) Appl. No.: 19/534,182

(22) Filed: Feb. 9, 2026

(30) Foreign Application Priority Data
Feb. 19, 2025 (DE) 10 2025 106 243.9

(51) Int. Cl. B23K 35/26; B23K 35/02; H10W 72/20

(52) U.S. Cl. CPC B23K 35/262; B23K 35/0244; B23K 35/025; B23K 35/26; H10W 72/245

(57) ABSTRACT

A diffusion soldering method is provided. The method includes applying a barrier layer on a high melting material, the barrier layer including metal and having at least one distinguishing property that distinguishes the barrier layer from a native oxide layer. A solder material is applied to a substrate. The solder material comprises a low-melting material. The high-melting material comprises the barrier layer. A diffusion soldering process is performed by bringing a material to be soldered into physical contact with the soldering material and heating it, whereby the low-melting material is melted, the barrier layer is at least partially dissolved, and then an intermetallic phase forms in the soldering material.

### CROSS-REFERENCE TO RELATED APPLICATION

This Utility Patent Application claims priority to German Patent Application No. 10 2025 106 243.9 filed February 19, 2025, which is incorporated herein by reference.

### TECHNICAL FIELD

Various embodiments relate generally to a diffusion soldering method and to a solder material.

### BACKGROUND

Remelting of a solder may cause problems for semiconductor functions. Therefore, high melting alloys with Pb, which is soon to be banned due to EU REACH regulations, are still in use.

Another way to prevent remelting is to have a system where all low melting phases are consumed during the soldering process.

Diffusion soldering is such a process, and it may provide an established lead free solder.

But its scope of application may be limited.

### SUMMARY

A diffusion soldering method is provided. The method includes applying a barrier layer on a high melting material, the barrier layer including metal or a metal compound and having at least one distinguishing property that distinguishes the barrier layer from a native oxide layer, wherein the at least one distinguishing property is selected from a group consisting of: a greater thickness, a different density, a different defect rate, and a different material; applying a solder material to a substrate, the solder material comprising a low-melting material and the high-melting material comprising the barrier layer; and performing a diffusion soldering process by bringing a material to be soldered into physical contact with the soldering material and heating it, whereby the low-melting material is melted, the barrier layer is at least partially dissolved, and then an intermetallic phase forms in the soldering material.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 schematically illustrates a diffusion soldering method according to a prior art;

FIG. 2 schematically illustrates a diffusion soldering method according to various embodiments;

FIG. 3 schematically illustrates a diffusion soldering method according to various embodiments;

FIG. 4 shows a flow diagram of a diffusion soldering method in accordance with various embodiments; and

FIG. 5 shows a periodic table with additional markings indicating elements suitable for forming compounds with other elements that may be suitable for the soldering method in accordance with various embodiments.

### DESCRIPTION

The following detailed description refers to the accompanying drawings that show, by way of illustration, specific details and embodiments in which the invention may be practiced.

The word "exemplary" is used herein to mean "serving as an example, instance, or illustration". Any embodiment or design described herein as "exemplary" is not necessarily to be construed as preferred or advantageous over other embodiments or designs.

Various aspects of the disclosure are provided for devices, and various aspects of the disclosure are provided for methods. It will be understood that basic properties of the devices also hold for the methods and vice versa. Therefore, for sake of brevity, duplicate description of such properties may have been omitted.

Usually, an AuSn system may be used for a diffusion solder, which is expensive and may be limited in application (typically, only as a backside metallization system).

These may still have limitations in that, at present, they work well for thin Sn layers either deposited on a wafer or as very thin metal foils, but at least not yet for thick metal layers.

For many applications, a thicker bondline or processing as a paste may be useful.

Therefore, a Ni/Sn solder paste has been developed, in which Ni particles are added to a Sn-based solder paste and lead to isothermal solidification of the solder at a soldering temperature, whereby an intermetallic compound is formed.

New developments expand the principle of isothermally solidifying solders (that form intermetallic compounds) to NiSn and CuSn systems. For example, fine metal (e.g. Ni or Cu) powder may be added to a solder base, which may for example include tin, and the Ni- and/or Cu-particles may then transfer all of the Sn to Sn₃Ni or Sn₃Cu.

This works in principle, allowing a wetting of the to be soldered surfaces and then a solidification at higher temperature.

But the formation of a rigid framework of IMC (InterMetallic Compound) is so fast and starts already below a melting temperature (also referred to as liquidus temperature) of the Sn. This may lead to the situation that the organic components of the solder have no time to evaporate and escape from under the top connection partner (e. g., a die) before solidification occurs. So, the bondline cannot collapse to form a dense interface. Instead, the result is a sponge like solder-joint. In other words, due to the fast reaction of the metal powders with the solder base, e. g., the Sn, the time the solder is actually liquid is too low for a formation of a good solder joint.

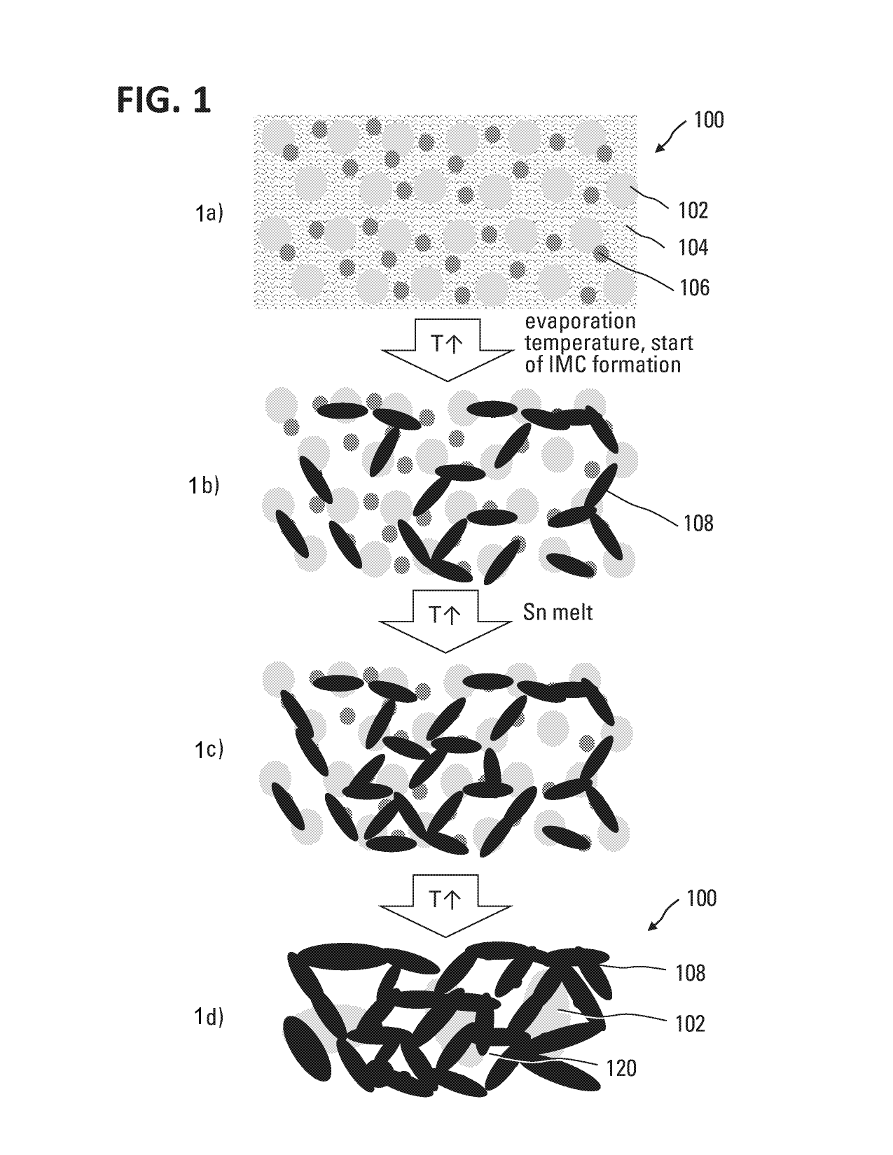

FIG. 1 shows a solder material 100 of the prior art to illustrate the above described reaction of the solder material to the heating. The solder material 100, as illustrated in panel 1a), includes a solvent 104, e. g., an organic solvent, e. g., a resin-solvent-mixture, and tin particles 102, for example as a solder paste, and nickel particles 106, which may be distributed in the solder paste 100.

As illustrated in panel 1b), already during the evaporation of the solvent 104 and before the melting of the tin (Sn), the intermetallic compound 108 starts to form.

The formation of the intermetallic compound continues during the melting of the tin (panel 1c)), and finally (see panel 1d)), a rigid skeleton of intermetallic compound 108 is formed, possibly with some remnants of tin 102 that have not reacted to form the intermetallic compound 108. Between and around the intermetallic compound 108, voids 120 have formed that have not had a chance to get filled by molten solder material, e. g., molten tin 102, before the formation of the intermetallic compound 108 set in. In other words, the bondline could not collapse to form a solid interface.

While in some cases, the sponge-like structure that forms through this process may be desired, other applications may benefit from a solid interface.

In various embodiments, a diffusion barrier is provided on metal powders of diffusion solders as described above, which delays the IMC formation and therefore increases the liquid time of the solder material to overcome the aboved described problem that the solidification of the solder joint by intermetallic compounds happens too fast.

In various embodiments, a solder material is provided that includes a high-melting material and a low-melting material. A barrier layer is provided on the high-melting material to inhibit the IMC formation even during soldering in the molten low-melting material. This may enable any voids to leave the solder melt before the IMC solidification of the solder joint.

The terms “high-melting material” and “low-melting material” refer to a melting point of the respective material, and the high-melting material may have a melting point that is higher than the melting point of the low-melting material. A melting point of the low-melting material may for example be in the range from about 120°C to about 450°C, for example in the range from about 200°C to about 250°C, and the high-melting material may have a melting point in a range from about 280°C to about 2000°C, for example in the range from about 450°C to about 1800°C.

In various embodiments, the barrier layer may have to withstand solder temperatures of more than 300°C (e. g., up to 420°C) for several seconds. This may exclude organic barrier layers. Thereby, a delayed IMC formation, and thus solidification, may be provided.

With this delayed solidification, even solder wire diffusion soldering or extended preform diffusion soldering may be possible.

Varous embodiments may enable a NiSn diffusion soldering paste, NiSn solder wire diffusion soldering, extended NiSn preform soldering, and a CuSn diffusion layer with Cu-particles in a solder alloy composition (for example SAC) matrix..

In various embodiments, the intermetallic phase formation may start only after a precisely tunable time after the Sn portion of the solder melted.

This may allow an organic portion of the solder (e. g., a solvent) to evaporate and be expelled from the bonding layer before the formation of the intermetallic compound.

In various embodiments, metal-oxides, metal-nitrides, and/or metals may be used for the barrier layer. Barrier layers including or consisting of said materials may prevent an interdiffusion of the high-melting material (e. g., Ni) and the low-melting material (e. g., Sn).

In various embodiments, the barrier layer may get attacked by the molten low-melting material (e. g., Sn) and dissolve with a certain rate. Once dissolved, the IMC formation starts and the solder solidifies.

Materials of the barrier layer may include e. g. NiO, Aₗ₂O₃,

In various embodiments, a natural (also referred to as “native”) oxidation of the high-melting (e. g., Ni) particles with air may not be sufficient to form a solder barrier in accordance with various embodiments, but may be too thin to control the thickness on a level that is suitable for delaying the IMC formation sufficiently.

Without a precise control of thickness and the kinetics, the phase-formation cannot be tuned accurately enough. Therefore, either a native oxide may be modified, e. g., thickened, another material may be deposited on the native oxide, or a different material may be applied to begin with.

In various embodiments, an accuracy of a layer thickness and the choice of materials may be increased, for example by using an ALD process for depositing the barrier layer onto the high-melting material, whereby the the barrier properties may be tuned. Possible materials for the barrier layer include for example Al₂O₃, CuO (here, the delay mechanism would be reduction by Sn), TiN, Ti, TiO₂, or, more generally, any of the following metals, alloys or compounds therefrom, or their oxides or nitrides: Ti, Cr, Fe, Mo, Nb, Ta, Al, Si, W, and Zr. In various embodiments, the barrier layer may include or consist of a layer stack including or consisting a combination of any of the above listed materials.

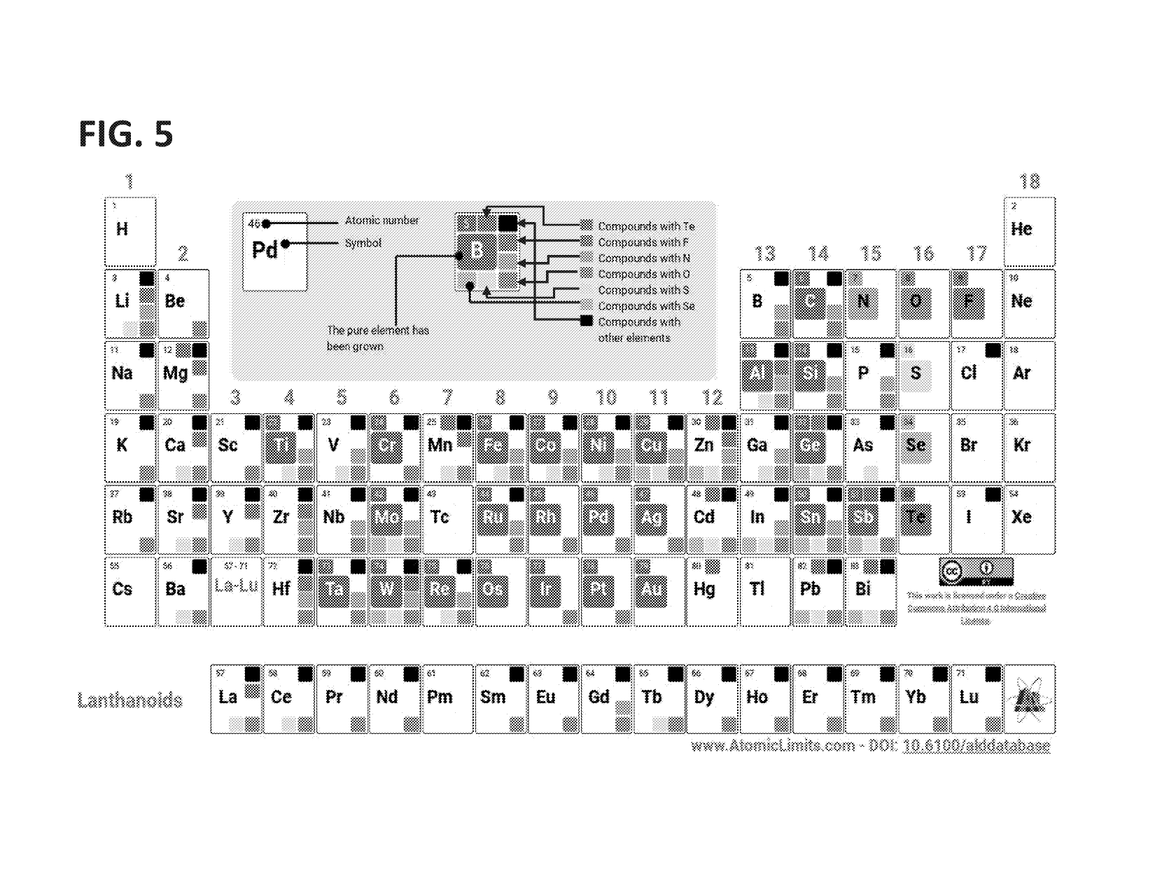

FIG. 5 shows a periodic table with additional markings indicating elements suitable for forming compounds with other elements that may be suitable, or even preferred due to their barrier properties, as a barrier layer that is applied to the high-melting material, e. g., on the high-melting particles to be used in the soldering method in accordance with various embodiments. Whether a given element in the table forms a compound with Te, F, N, O, S, Se, or with other elements, is coded by greyscale and position of an indicator box arranged around the respective symbol for the element, as explained in the legend in the top box. Lines have been added for clarity to indicate the pairing of compounds and boxes, since the periodic table had initially been designed in color, such that the greyscale representation shown here makes an identification of a possible compound more difficult.

In various embodiments, the high-melting material may be provided as particles, for example as a powder, on which the barrier layer may be applied, before including the particles (e. g., the powder) with the barrier layer in the solder material, e. g., the solder layer.

The barrier layer may in various embodiments be used in solder pastes, and also on a low-melting material, e. g. on particles, of a metal mix for solder-wire manufacturing. In the latter, the barrier layer may need to be able to withstand also a wire-extrusion thermal budget.

In various embodiments, the barrier layer may be applied via chemical deposition or physical deposition, for example using atomic layer deposition, evaporation or sputtering, wet chemical deposition; electroless deposition; galvanic deposition, electrophoretic deposition, and thermal oxidation.

The applying the barrier layer may lead to a total thickness of the barrier layer (which may include a thickened native oxide and a barrier layer stack) in a range of from about 2 nm to about 70 nm, for example in a range of from about 3 nm to about 50 nm.

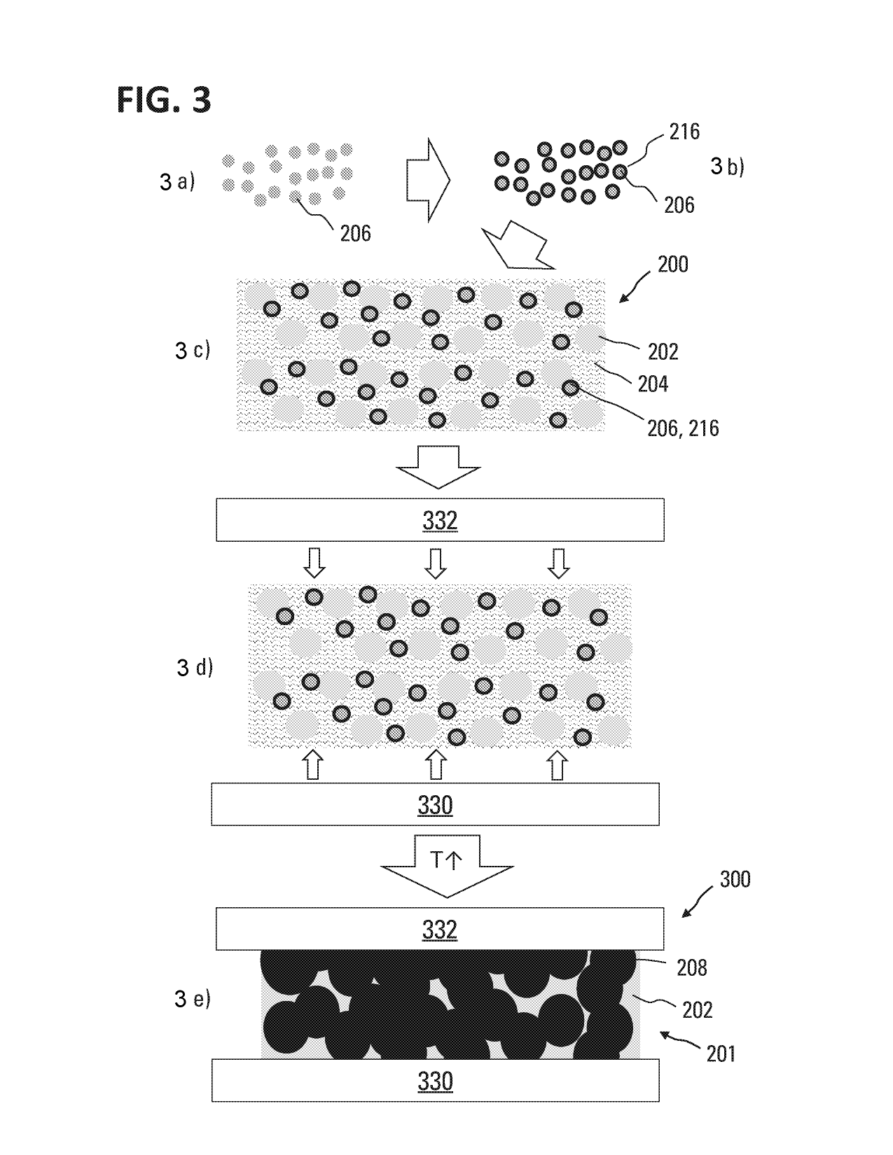

FIG. 3 schematically illustrates, in panels 3a), 3b), 3c), 3d) and 3e), a diffusion soldering method according to various embodiments.

The method includes applying a barrier layer 216 on a high-melting material 206, the barrier layer 216 including metal or a metal compound and having a greater thickness, different density, different defect rate, and/or being a different material than a native oxide layer. In FIG. 3, the process of applying the barrier layer 216 on the high-melting material 206 is illustrated in the transition from panel 3a) to panel 3b).

In various embodiments, the high-melting material 206 may be provided as particles. Any of the above described methods may be used for applying, e g., depositing, a barrier layer 216 having a thickness in the above specified thickness range. The high-melting material 206 may for example include or consist of at least one metal selected from the group consisting of Ni, Cu, Ag, Au, Pt, and Pd.

The barrier layer 216 may, in various embodiments, consist, or essentially consist, of the metal or metal compound. The metal or metal compound may be selected from a group consisting of Ag; Au; Cu; Ni; NiP; Pd; Al/Ti/NiV/Ag; Al/Ti/NiV/Au; Ti/NiV/Ag; Ti/NiV/Au; and NiSi/Ti/NiV/Ag.

The barrier layer 216 may, in various embodiments, include or consist essentially of a metal oxide, wherein the metal oxide optionally includes an oxide and/or a nitride of at least one of the group of metals specified above.

The method may further include applying a solder material 200 to a substrate 330, the solder material 200 including a low-melting material 202 and the high-melting material 206 (with the barrier layer 216 applied thereon).This is illustrated in panel 3d). Optionally, a material to be soldered 332, e. g., a top connection partner, may be arranged on top of the solder material 200. The solder material 200 may be arranged to contact the substrate 330 (and the material to be soldered 332), and may be configured to form a solid interface with the substrate after the soldering, and may optionally join the substrate and the top connection partner 332, which may optionally be for example a semiconductor chip.

This may mean that the high-melting material 206 (with the barrier layer 216 applied thereon) is included in the solder material 200, for example mixed with a solder base that may include or consist of components essentially as known in the art for diffusion solders, e. g., a solvent and a resin, or other suitable organic components. The low-melting material 202 may be added to the solder 200 before, after, or together with the high-melting material 206, 216. The forming of the solder 200 is schematically illustrated in panel 3c) of FIG. 3.

The method may further include performing a diffusion soldering process by bringing a material to be soldered into physical contact with the soldering material (the arranging of the top connection partner 332) and by heating it, whereby the low-melting material is melted, the barrier layer 216 is at least partially dissolved, and then an intermetallic phase 208 forms in the soldering material 200.

The heating is indicated in FIG. 3 by the arrow with “T↑”,

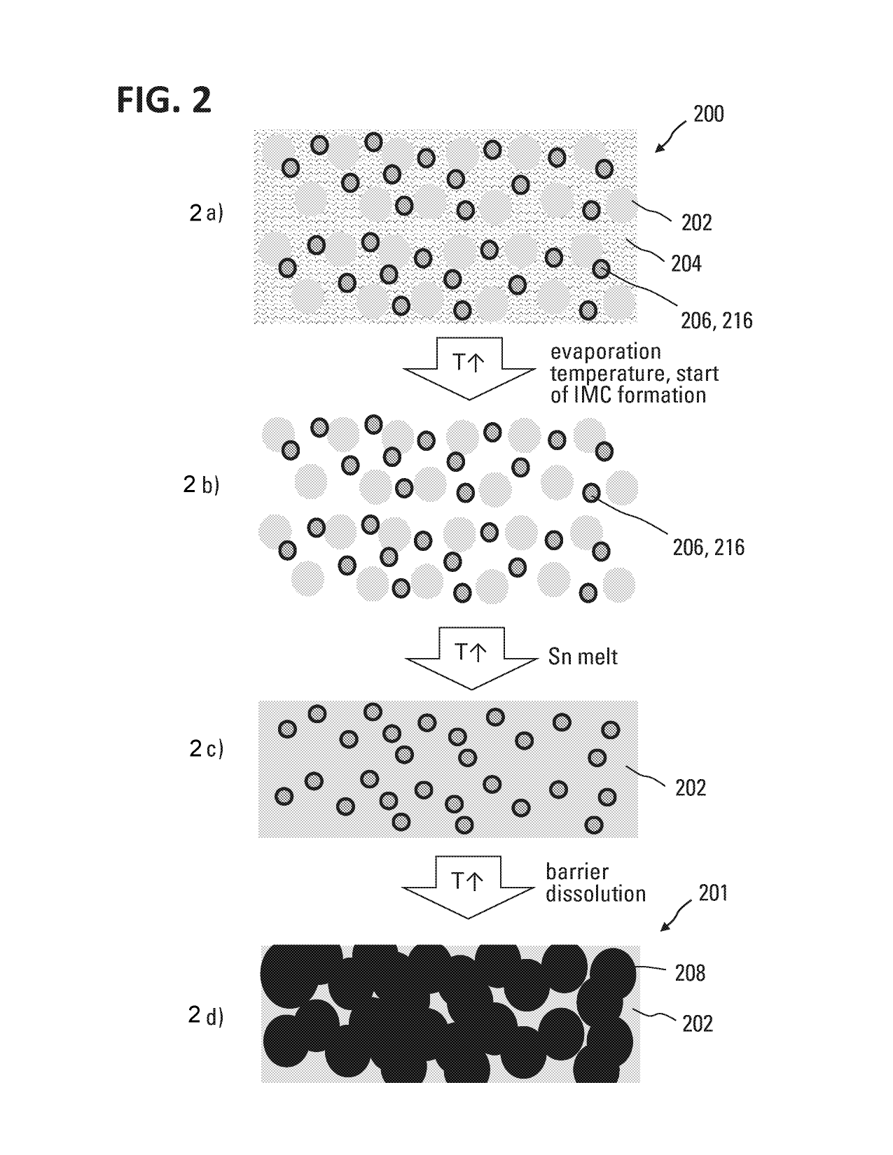

FIG. 2 illustrates, in panels 2a), 2b), 2c) and 2d), in more detail how the solder 200 reacts to the soldering (in particular, the heating). The solder 200 of panel 2a) of FIG. 2 is essentially identical to the solder 200 of panel 3c) of FIG. 3.

It is essential that, during the soldering process, most of the solder base 204 evaporates first (see panel 2b)), before the barrier layer 216 is destroyed, e. g., dissolved.

A material (or for example a sequence of different materials, e. g., for a layer stack) of the barrier layer 216, a thickness of the barrier layer 216, etc. may be tuned to reproduce as closely as possible an intended behaviour with increasing temperature, for example a temperature at which the barrier layer 206, 216 dissolves, which is supposed to occur after a melting of the low-melting material 202, as illustrated in panel 2c) of FIG. 2.

In various embodiments, it may be sufficient that a substantial fraction, for example at least 50 %, e. g., at least 60 %, e. .g, at least 70 %, e. g., at least 80 %, e. .g, at least 90 %, of the low-melting material 202 is molten before the barrier layer 206 is dissolved. That the barrier layer 216 may still be intact when the low-melting material 202 is molten is illustrated as an example in panel 2c) of FIG. 2.

As further illustrated in FIG. 2, the liquefied low-melting material 202 has a chance to fill the voids left in the solder material 200 after the evaporation of the solder base 204. The formation of the rigid intermetallic compound 208 may thus be delayed, by the barrier layer 216, until after the voids have been filled. Thus, a solid solder interface 201 (also referred to as solder connection) is achieved.

In various embodiments, the high-melting material 206, 216 may be formed as a homogeneous group, for example as a group in which the high- melting material 206 is the same metal throughout, e. g., for all particles, a size/shape of the high-melting material is the same throughout, e. g., all particles may have the same size and shape, and the same material of the barrier layer 216 may be used throughout, e g., on all particles.

In various embodiments, the high-melting material 206, 216 may be formed as a heterogeneous group, for example as a group in which the high-melting material 206 includes different metals, for example particles including or consisting of different metals, and/or a size/shape of the high-melting material may vary, e. g., some particles of the high-melting material 206 may have a different size and/or shape than some others, and/or materials of the barrier layer 216 applied to a portion of the high-melting material 206, e. g., to some particles, may differ from materials of the barrier layer 216 applied to a different portion of the high-melting material 206, e. g., to other particles.

In various embodiments, the low-melting material 202 may be formed as a homogeous group, for example as a group in which the low-melting material 202 is the same metal throughout, e. g., for all particles, and a size/shape of the low-melting material is the same throughout, e. g., all particles may have the same size and shape.

In various embodiments, the low-melting material 202 may be formed as a heterogeneous group, for example as a group in which the low-melting material 202 includes different metals, for example particles including or consisting of different metals, and/or a size/shape of the low-melting material 202 may vary, e. g., some particles of the low-melting material 202 may have a different size and/or shape than some others.

The low-melting material 202 may for example include or consist of any of the following group of metals: Bi; Sn; Ga; Zn; and In.

In various embodiments, the intermetallic phase 208 may be formed between the low-melting material 202 and the high-melting material 206. In addition, the intermetallic phase may optionally be formed between the low-melting material 202 of the solder 200 and an undissolved portion of the barrier layer 216.

The solder material 200 may in various embodiments be provided as solder paste, solder wire, solder preform, or solder film.

In various embodiments, the method may further include modifying, e. g., thermally oxidizing or nitriding the barrier layer 216.

In various embodiments, the barrier layer 216 may include a first barrier layer of a first material and a second barrier layer of a second material, wherein the first material and the second material are different. The first barrier layer may be applied directly on the high-melting material 206, and the second barrier layer may be applied directly on the first barrier layer.

In various embodiments, the second barrier layer may have a layer thickness in a range from about 2 nm to about 70 nm, for example in a range from about 3 nm to about 50 nm.

The solder material 200 may be lead-free.

The substrate 330 may be one of a group of substrates, the group consisting, e. g., of a leadframe; a PCB; and a clip.

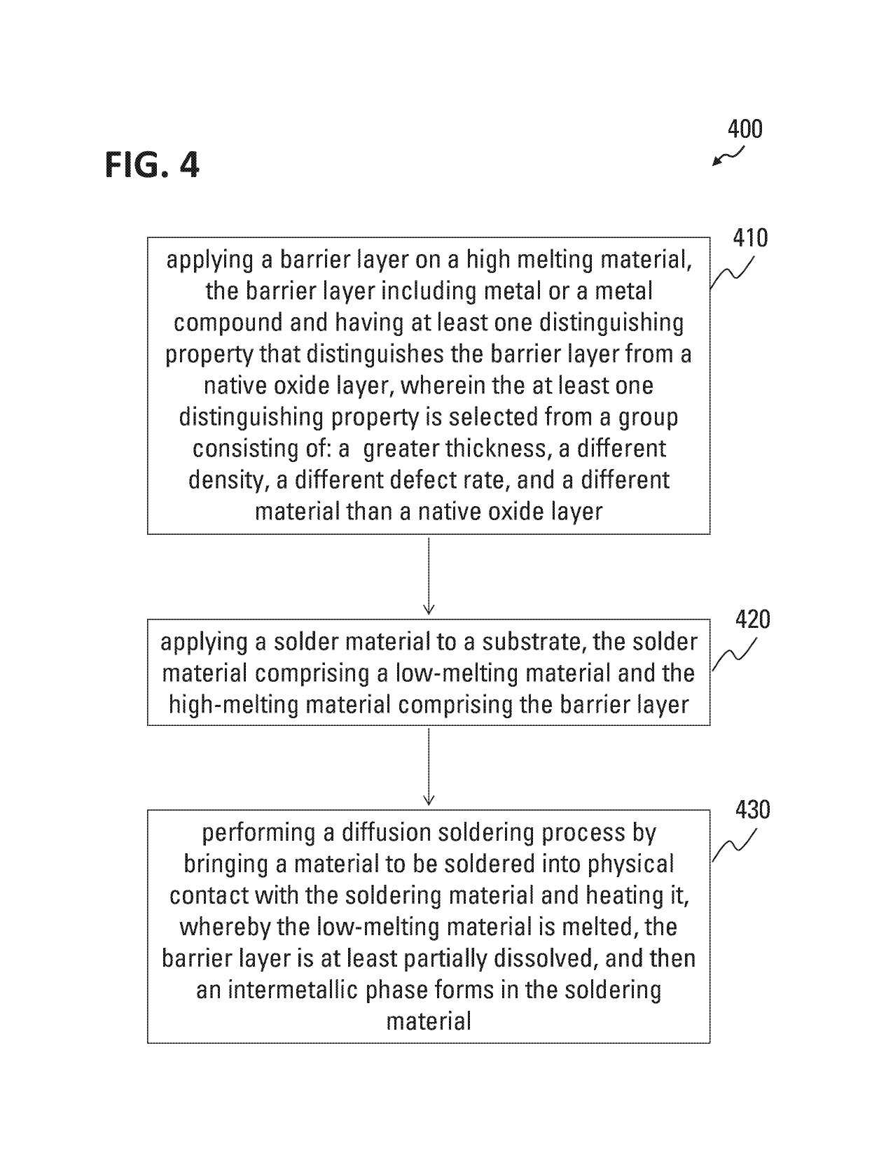

FIG. 4 shows a flow diagram 400 of a diffusion soldering method in accordance with various embodiments.

The method includes applying a barrier layer on a high-melting material, the barrier layer including metal or a metal compound and having at least one distinguishing property that distinguishes the barrier layer from a native oxide layer, wherein the at least one distinguishing property is selected from a group consisting of: a greater thickness, a different density, a different defect rate, and a different material than a native oxide layer (410), applying a solder material to a substrate, the solder material including a low-melting material and the high-melting material including the barrier layer (420); and performing a diffusion soldering process by bringing a material to be soldered into physical contact with the soldering material and heating it, whereby the low-melting material is melted, the barrier layer is at least partially dissolved, and then an intermetallic phase forms in the soldering material (430).

Various examples will be illustrated in the following:

Example 1 is a diffusion soldering method. The method includes applying a barrier layer on a high-melting material, the barrier layer including metal or a metal compound and having at least one distinguishing property that distinguishes the barrier layer from a native oxide layer, wherein the at least one distinguishing property is selected (optionally two or more are selected) from a group consisting of: a greater thickness, a different density, a different defect rate, and a different material than a native oxide layer; applying a solder material to a substrate, the solder material including a low-melting material and the high-melting material including the barrier layer; and performing a diffusion soldering process by bringing a material to be soldered into physical contact with the soldering material and heating it, whereby the low-melting material is melted, the barrier layer is at least partially dissolved, and then an intermetallic phase forms in the soldering material.

In Example 2, the subject-matter of Example 1 may optionally include that the intermetallic phase is formed between the low-melting material of the solder material and the high-melting material of the solder material.

In Example 3, the subject-matter of Example 1 may optionally include that the intermetallic phase is formed between the low-melting material of the solder and an undissolved portion of the barrier layer.

In Example 4, the subject-matter of any of Examples 1 to 3 may optionally include that the solder material is provided as solder paste; solder wire; solder preform; or solder film.

In Example 5, the subject-matter of any of Examples 1 to 4 may optionally include that the barrier layer consists essentially of the metal or metal compound.

In Example 6, the subject-matter of any of Examples 1 to 5 may optionally include that the metal or metal compound is selected from a group consisting of Ag; Au; Cu; Ni; NiP; Pd; Pt, Al, Al/Ti/NiV/Ag; Al/Ti/NiV/Au; Ti/NiV/Ag; Ti/NiV/Au; and NiSi/Ti/NiV/Ag.

In Example 7, the subject-matter of any of Examples 1 to 6 may optionally include that the barrier layer includes or consists essentially of a metal oxide.

In Example 8, the subject-matter of Example 6 may optionally include that the barrier layer includes or consists essentially of a metal oxide, and wherein the metal oxide includes an oxide of at least one of the group of metals.

In Example 9, the subject-matter of any of Examples 1 to 8 may optionally include that the barrier layer includes or consists essentially of a metal nitride.

In Example 10, the subject-matter of Example 6 may optionally include that the barrier layer includes or consists essentially of a metal nitride, and wherein the metal nitride includes a nitride of at least one of the group of metals.

In Example 11, the subject-matter of any of Examples 1 to 10 may optionally include that applying the barrier layer includes thermal oxidizing.

In Example 12, the subject-matter of any of Examples 1 to 11 may optionally further include modifying the barrier layer.

In Example 13, the subject-matter of Example 12 may optionally include that modifying the barrier layer includes thermally oxidizing the barrier layer or nitriding the barrier layer.

In Example 14, the subject-matter of any of Examples 1 to 13 may optionally include that applying the barrier layer includes chemical deposition or physical deposition.

In Example 15, the subject-matter of any of Examples 1 to 14 may optionally include that applying the barrier layer includes atomic layer deposition, evaporation or sputtering.

In Example 16, the subject-matter of any of Examples 1 to 14 may optionally include that the application of the barrier layer includes at least one of wet chemical deposition; electroless deposition; galvanic deposition; and electrophoretic deposition.

In Example 17, the subject-matter of any of Examples 1 to 16 may optionally include that the barrier layer has a layer thickness in a range of from about 2 nm to about 70 nm, for example in a range of from about 3 nm to about 50 nm.

In Example 18, the subject-matter of any of Examples 1 to 17 may optionally include that the barrier layer includes a first barrier layer of a first material and a second barrier layer of a second material, wherein the first material and the second material are different.

In Example 19, the subject-matter of Example 18 may optionally include that the second barrier layer has a layer thickness in a range from about 2 nm to about 70 nm, for example in a range from about 3 nm to about 50 nm.

In Example 20, the subject-matter of any of Examples 1 to 19 may optionally include that the solder material is lead-free.

In Example 21, the subject-matter of any of Examples 1 to 20 may optionally include that the substrate is one of a group of substrates, the group consisting of, e. g., a leadframe; a PCB; and a clip.

Example 22 is a solder material. The solder material includes a high-melting material having a barrier layer applied thereto, wherein the barrier layer includes metal or a metal compound and has at least one distinguishing property that distinguishes the barrier layer from a native oxide layer, wherein the at least one distinguishing property is selected (optionally two or more are selected) from a group consisting of: a greater thickness, a different density, a different defect rate, and a different material than a native oxide layer; and low-melting material; wherein the solder material is adapted such that during a soldering process the barrier layer is broken and at least partially dissolved and that then an intermetallic phase forms in the solder material.

In Example 23, the subject-matter of Example 22 may optionally include that the high-melting material includes or consists of particles.

In Example 24, the subject-matter of Example 22 or 23 may optionally include that the metal or metal compound is selected from a group consisting of Ag; Au; Cu; Ni; NiP; Pd; Pt, Al, Al/Ti/NiV/Ag; Al/Ti/NiV/Au; Ti/NiV/Ag; Ti/NiV/Au; and NiSi/Ti/NiV/Ag.

In Example 25, the subject-matter of any of Examples 22 to 24 may optionally include that the intermetallic phase is formed between the low-melting material of the solder material and the high-melting material of the solder material.

In Example 26, the subject-matter of any of Examples 22 to 25 may optionally include that the intermetallic phase is formed between the low-melting material of the solder and an undissolved portion of the barrier layer.

In Example 27, the subject-matter of any of Examples 22 to 26 may optionally include that the barrier layer includes or consists essentially of a metal oxide and/or a metal nitride.

In Example 28, the subject-matter of Example 24 may optionally include that the barrier layer includes or consists essentially of a metal nitride, and wherein the metal nitride includes a nitride of at least one of the metals from the group.

In Example 29, the subject-matter of Example 24 may optionally include that the barrier layer includes or consists essentially of a metal oxide, and wherein the metal oxide includes an oxide of at least one of the metals from the group.

In Example 30, the subject-matter of any of Examples 22 to 29 may optionally include that the barrier layer has a layer thickness in a range of from about 2 nm to about 70 nm, for example in a range of from about 3 nm to about 50 nm.

In Example 31, the subject-matter of any of Examples 22 to 30 may optionally include that the barrier layer includes a first barrier layer of a first material and a second barrier layer of a second material, wherein the first material and the second material are different, wherein, optionally, the second layer consists of tin.

In Example 32, the subject-matter of Example 31 may optionally include that the second barrier layer has a layer thickness in a range of from about 2 nm to about 70 nm, for example in a range of from about 3 nm to about 50 nm.

In Example 33, the subject-matter of any of Examples 22 to 32 may optionally include that the solder material is lead-free.

Example 34 is a method of forming a solder material. The method includes applying a barrier layer to a high-melting material, wherein the barrier layer includes metal or a metal compound and has a greater thickness and/or is a different material than a native oxide layer; and combining the high-melting material with the barrier layer with a low-melting material; wherein the solder material is adapted such that, during a soldering process, the barrier layer is melted and at least partially dissolved, and that then, an intermetallic phase forms in the solder material.

In Example 35, the subject-matter of Example 34 may optionally include that the high-melting material includes or consists of particles.

In Example 36, the subject-matter of Example 34 or 35 may optionally include that the metal or metal compound is selected from a group consisting of Ag; Au; Cu; Ni; NiP; Pd; Pt, Al; Al/Ti/NiV/Ag; Al/Ti/NiV/Au; Ti/NiV/Ag; Ti/NiV/Au; and NiSi/Ti/NiV/Ag.

In Example 37, the subject-matter of any of Examples 34 to 36 may optionally include that the solder material is configured to form the intermetallic phase between the low-melting material of the solder material and the high-melting material of the solder material.

In Example 38, the subject-matter of any of Examples 34 to 37 may optionally include that the solder material is configured to form the intermetallic phase between the low-melting material of the solder and an undissolved portion of the barrier layer.

In Example 39, the subject-matter of any of Examples 34 to 26 may optionally include that the applying the barrier layer includes or consists essentially of oxidizing, e. g., thermally, or nitriding a metal, optionally the metal of the high-melting material or a different metal.

In Example 40, the subject-matter of Example 36 may optionally include that the barrier layer includes or consists essentially of a metal nitride, and wherein the metal nitride includes a nitride of at least one of the metals from the group.

In Example 41, the subject-matter of Example 36 may optionally include that the barrier layer includes or consists essentially of a metal oxide, and wherein the metal oxide includes an oxide of at least one of the metals from the group.

In Example 42, the subject-matter of any of Examples 34 to 41 may optionally include that the barrier layer has a layer thickness in a range of from about 2 nm to about 70 nm, for example in a range of from about 3 nm to about 50 nm.

In Example 43, the subject-matter of any of Examples 34 to 42 may optionally include that the barrier layer includes a first barrier layer of a first material and a second barrier layer of a second material, wherein the first material and the second material are different.

In Example 44, the subject-matter of Example 43 may optionally include that the second barrier layer has a layer thickness in a range of from about 2 nm to about 70 nm, for example in a range of from about 3 nm to about 50 nm.

In Example 45, the subject-matter of any of Examples 34 to 44 may optionally include that the solder material is lead-free.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A diffusion soldering method, the method comprising:
applying a barrier layer on a high melting material, the barrier layer comprising metal or a metal compound and having at least one distinguishing property that distinguishes the barrier layer from a native oxide layer, wherein the at least one distinguishing property is selected from a group consisting of: a greater thickness, a different density, a different defect rate, and a different material than a native oxide layer;
applying a solder material to a substrate, the solder material comprising a low-melting material and the high-melting material comprising the barrier layer; and
performing a diffusion soldering process by bringing a material to be soldered into physical contact with the soldering material and heating it, whereby the low-melting material is melted, the barrier layer is at least partially dissolved, and then an intermetallic phase forms in the soldering material.

2. The method according to claim 1,
wherein the intermetallic phase is formed between the low-melting material of the solder material and the high-melting material of the solder material.

3. The method according to claim 1,
wherein the intermetallic phase is formed between the low-melting material of the solder and an undissolved portion of the barrier layer.

4. The method according to claim 1,
wherein the solder material is provided as:
solder paste;
solder wire;
solder preform; or
solder film.

5. The method according to claim 1,
wherein the barrier layer consists essentially of the metal or metal compound.

6. The method according to claim 1,
wherein the metal or metal compound is selected from a group consisting of:
Ag;
Au;
Cu;
Ni;
NiP;
Pd;
Pt
Al
Al/Ti/NiV/Ag;
Al/Ti/NiV/Au;
Ti/NiV/Ag;
Ti/NiV/Au; and
NiSi/Ti/NiV/Ag.

7. The method according to claim 1,
wherein the barrier layer comprises or consists essentially of a metal oxide.

8. The method according to claim 6,
wherein the barrier layer comprises or consists essentially of a metal oxide, and wherein the metal oxide comprises an oxide of at least one of the group of metals.

9. The method according to claim 1,
wherein the barrier layer comprises or consists essentially of a metal nitride.

10. The method according to claim 6,
wherein the barrier layer comprises or consists essentially of a metal nitride, and wherein the metal nitride comprises a nitride of at least one of the group of metals.

11. The method according to claim 1,
wherein applying the barrier layer comprises thermal oxidizing.

12. The method according to claim 1, further comprising:
modifying the barrier layer.

13. The method according to claim 12,
wherein modifying the barrier layer comprises thermally oxidizing the barrier layer or nitriding the barrier layer.

14. The method according to claim 1,
wherein applying the barrier layer comprises chemical deposition or physical deposition.

15. The method according to claim 1,
wherein applying the barrier layer comprises atomic layer deposition, evaporation or sputtering.

16. The method according to claim 1,
wherein the application of the barrier layer comprises at least one of:
wet chemical deposition;
electroless deposition;
galvanic deposition; and
electrophoretic deposition.

17. The method according to claim 1,
wherein the barrier layer has a layer thickness in a range of from about 2 nm to about 70 nm, for example in a range of from about 3 nm to about 50 nm.

18. The method according to claim 1,
wherein the barrier layer comprises a first barrier layer of a first material and a second barrier layer of a second material, wherein the first material and the second material are different.

19. The method according to claim 18,
wherein the second barrier layer has a layer thickness in a range from about 2 nm to about 70 nm, for example in a range from about 3 nm to about 50 nm.

20. The method according to claim 1,
wherein the solder material is lead-free.

21. The method according to claim 1,
wherein the substrate is one of a group of substrates, the group consisting of:
a leadframe;
a PCB; and
clip.

22. A solder material, comprising:
high-melting material having a barrier layer applied thereto, wherein the barrier layer comprises metal or a metal compound and has at least one distinguishing property that distinguishes the barrier layer from a native oxide layer, wherein the at least one distinguishing property is selected from a group consisting of: a greater thickness, a different density, a different defect rate, and a different material than a native oxide layer; and
low-melting material;
wherein the solder material is adapted such that during a soldering process the barrier layer is melted and at least partially dissolved and that then an intermetallic phase forms in the solder material.

23. The solder material according to claim 22,
wherein the high-melting material comprises or consists of particles.

24. The solder material according to claim 22,
wherein the metal or metal compound is selected from a group consisting of:
Ag;
Au;
Cu;
Ni;
NiP;
Pd;
Pt;
Al;
Al/Ti/NiV/Ag;
Al/Ti/NiV/Au;
Ti/NiV/Ag;
Ti/NiV/Au; and
NiSi/Ti/NiV/Ag.

25. The solder material according to claim 22,
wherein the intermetallic phase is formed between the low-melting material of the solder material and the high-melting material of the solder material.

26. The solder material according to claim 22,
wherein the intermetallic phase is formed between the low-melting material of the solder and an undissolved portion of the barrier layer.

27. The solder material according to claim 22,
wherein the barrier layer comprises or consists essentially of a metal oxide and/or a metal nitride.

28. The solder material according to claim 24,
wherein the barrier layer comprises or consists essentially of a metal nitride, and wherein the metal nitride comprises a nitride of at least one of the metals from the group.

29. The solder material according to claim 24,
wherein the barrier layer comprises or consists essentially of a metal oxide, and wherein the metal oxide comprises an oxide of at least one of the metals from the group.

30. 30. The solder material according to claim 22,
wherein the barrier layer has a layer thickness in a range of from about 2 nm to about 70 nm, for example in a range of from about 3 nm to about 50 nm.

31. The solder material according to claim 22,
wherein the barrier layer comprises a first barrier layer of a first material and a second barrier layer of a second material, wherein the first material and the second material are different, wherein, optionally, the second layer consists of tin.

32. The solder material according to claim 31,
wherein the second barrier layer has a layer thickness in a range of from about 2 nm to about 70 nm, for example in a range of from about 3 nm to about 50 nm.

33. The solder material according to claim 22,
wherein the solder material is lead-free.
